(19) United States
(12) Patent Application Publication
(10) Pub. No.: US 2016/0225336 A1
(43) Pub. Date: Aug. 4, 2016

(54) SHIFT REGISTER UNIT, ITS DRIVING METHOD, GATE DRIVER CIRCUIT AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Honggang GU, Beijing (CN); Xiaohe LI, Beijing (CN); Xianjie SHAO, Beijing (CN); Zhifu DONG, Beijing (CN); Xiaojie ZHANG, Beijing (CN); Lili YAO, Beijing (CN)

(73) Assignees: HEFEI BOE OPTOELECTRONICS TECHNOLOGY CO., LTD., Hefei (CN); BOE TECHNOLOGY GROUP CO., LTD., Beijing (CN)

(21) Appl. No.: 14/740,940

(22) Filed: Jun. 16, 2015

(30) Foreign Application Priority Data
Jan. 30, 2015 (CN) 201510051457.X

(51) Int. Cl. G09G 3/36; G11C 19/28

(52) U.S. Cl. CPC G09G 3/3696; G09G 3/3648; G11C 19/28; G09G 2300/0426; G09G 2310/0286; G09G 2310/08; G09G 2310/061

(57) ABSTRACT

A shift register unit includes an input end, a gate driving signal output end, a resetting end, a pull-up transistor, a pull-down transistor, a pull-down node control module, a pull-up node control module and an output noise reduction transistor. The pull-down node control module is configured to pull up a potential of a pull-down node to a high potential at a first noise reduction stage, so as to turn on the pull-down transistor and enable the gate driving signal output end to output a low level. The pull-up node control module is configured to pull down a potential of the pull-up node to a low potential at a resetting stage, and maintain the potential of the pull-up node to be at a low potential at the first noise reduction stage and a second noise reduction stage, so as to turn off the pull-up transistor.

### CROSS-REFERENCE TO RELATED APPLICATION

The present application claims a priority of the Chinese patent application No. 201510051457.X filed on Jan. 30, 2015, which is incorporated herein by reference in its entirety.

### TECHNICAL FIELD

The present disclosure relates to the field of display technology, in particular to a shift register unit, its driving method, a gate driver circuit and a display device.

### BACKGROUND

Along with the development of the liquid crystal display technology, a high resolution and a narrow bezel have become a new trend of the liquid crystal display technology. The application of a gate shift register in a display panel is one of the important methods so as to achieve narrow bezel and the high resolution.

A driver of a thin film transistor-liquid crystal display (TFT-LCD) mainly includes a gate driver circuit and a data driver circuit. The gate driver circuit consists mainly of a plurality of stages of shift register units, and each stage of the shift register unit is connected to a gate line, so as to progressively scan and drive a pixel TFT through an output signal from the shift register unit. However, it is impossible for the existing shift register unit to prevent the occurrence of a coupling voltage generated due to a clock signal, and thereby it is impossible to minimize noise interference while achieving bi-direction scanning. In addition, a large number of TFTs are adopted, so it is unable to achieve the narrow bezel, reduce the production cost and improve the yield thereof.

### SUMMARY

A main object of the present disclosure is to provide a shift register unit, its driving method, a gate driver circuit and a display device so as to, as compared with the related art, minimize noise interference while achieving threshold voltage compensation and bi-direction scanning and reduce the number of TFTs, thereby to provide a narrow bezel.

In one aspect, the present disclosure provides in one embodiment a shift register unit, including an input end, a gate driving signal output end, and a resetting end. The shift register unit further includes:

a pull-up transistor, a gate electrode of which is connected to a pull-up node, a first electrode of which is configured to receive a first clock signal, and a second electrode of which is connected to the gate driving signal output end;

a pull-down transistor, a gate electrode of which is connected to a pull-down node, a first electrode of which is connected to the gate driving signal output end, and a second electrode of which is configured to receive a first low level;

a pull-down node control module configured to receive the first low level and the first clock signal, connected to the pull-up node and the pull-down node, and configured to control the pull-down node to be at a low potential at a pre-charging stage of each display period, maintain the pull-down node at the low potential at an outputting stage of each display period, pull up a potential of the pull-down node to a high potential at a first noise reduction stage of each display period so as to turn on the pull-down transistor, and thereby to enable the gate driving signal output end to output a low level;

a pull-up node control module configured to receive a high level, the first low level and a second low level, connected to the pull-up node, the pull-down node, the input end and the resetting end, and configured to, pull up a potential of the pull-up node to a high potential at the pre-charging stage of each display period, control the potential of the pull-up node to be bootstrapped at the outputting stage of each display period so as to maintain the pull-up transistor in an on state and enable the gate driving signal output end to output the first clock signal, pull down the potential of the pull-up node to a low potential at a resetting stage of each display period, and maintain the pull-up node to be at a low potential at the first noise reduction stage and a second noise reduction stage of each display period so as to turn off the pull-up transistor; and

an output noise reduction transistor, a gate electrode of which is configured to receive a second clock signal, a first electrode of which is connected to the gate driving signal output end, a second electrode of which is configured to receive the first low level, and which is configured to be turned on at the pre-charging stage, the resetting stage and the second noise reduction stage of each display period so as to perform noise reduction on the gate driving signal output end, thereby to enable the gate driving signal output end to output a low level.

The first clock signal is of a phase reverse to the second clock signal.

During the implementation, the pull-down node control module is further configured to receive the second clock signal, and pull up the potential of the pull-down node to a high potential at the resetting stage and the second noise reduction stage of each display period, so as to control the pull-up node to be at a low potential by the pull-up node control module and enable the gate driving signal output end to output a low level by the output noise reduction transistor.

During the implementation, the pull-down node control module includes:

a first pull-down node control transistor, a gate electrode of which is connected to the pull-up node, a first electrode of which is connected to the pull-down node, and a second electrode of which is configured to receive the first low level; and

a pull-down node control capacitor connected between the pull-down node and a first clock signal output end.

During the implementation, the pull-down node control module further includes:

a second pull-down node control transistor, a gate electrode of which is configured to receive the second clock signal, a first electrode of which is connected to the pull-down node, and a second electrode of which is configured to receive the second clock signal.

During the implementation, the pull-up node control module includes a first transistor, a second transistor, a pull-up node control transistor and a storage capacitor. A gate electrode of the pull-up node control transistor is connected to the pull-down node, a first electrode thereof is configured to receive the first low level, and a second electrode thereof is connected to the pull-up node. The storage capacitor is connected between the pull-up node and the gate driving signal output end. During forward scanning, a gate electrode of the first transistor is connected to the input end, a first electrode of the first transistor is configured to receive the high level, a second electrode of the first transistor is connected to the pull-up node, a gate electrode of the second transistor is connected to the resetting end, a first electrode of the second transistor is connected to the pull-up node, and a second electrode of the second transistor is configured to receive the second low level. During backward scanning, the gate electrode of the first transistor is connected to the resetting end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

In another aspect, the present disclosure provides in one embodiment a method for driving the above-mentioned shift register unit, including, within each display period and during forward scanning and backward scanning, steps of:

at a pre-charging stage, receiving a high level by an input end, receiving a low level by a resetting end, enabling a first clock signal to be at a low level, enabling a second clock signal to be at a high level, pulling up a potential of a pull-up node to a high potential by a pull-up node control module so as to turn on a pull-up transistor, controlling a pull-down node to be at a low potential by a pull-down node control module so as to turn off a pull-down transistor, turn on an output noise reduction transistor and enable a gate driving signal output end to output a low level;

at an outputting stage, receiving a low level by the input end, receiving a low level by the resetting end, enabling the first clock signal to be at a high level, enabling the second clock signal to be at a low level, bootstrapping the potential of the pull-up node by the pull-up node control module so as to maintain the pull-up transistor in an on state and enable the gate driving signal output end to output the first clock signal, and maintaining the potential of the pull-down node to be at a low potential by the pull-down node control module;

at a resetting stage, receiving a low level by the input end, receiving a high level by the resetting end, enabling the first clock signal to be at a low level, enabling the second clock signal to be at a high level, pulling down the potential of the pull-up node to a low potential by the pull-up node control module, so as to turn on the output noise reduction transistor, perform noise reduction on the gate driving signal output end, and enable the gate driving signal output end to output a low level;

at a first noise reduction stage, receiving a low level by the input end, receiving a low level by the resetting end, enabling the first clock signal to be at a high level, enabling the second clock signal to be at a low level, maintaining the potential of the pull-up node to be a low potential by the pull-up node control module so as to turn off the pull-up transistor, and pulling up the potential of the pull-down node to a high potential by the pull-down node control module so as to turn on the pull-down transistor and enable the gate driving signal output end to output a low level; and

at a second noise reduction stage, receiving a low level by the input end, receiving a low level by the resetting end, enabling the first clock signal to be at a low level, enabling the second clock signal to be at a high level, maintaining the potential of the pull-up node to be a low potential by the pull-up node control module so as to turn off the pull-up transistor, turn on the output noise reduction transistor, thereby to perform noise reduction on the gate driving signal output end and enable the gate driving signal output end to output a low level.

During the implementation, the method further includes performing the steps at the first noise reduction stage and the second noise reduction stage repeatedly after the second noise reduction stage of one display period and before a next display period.

During the implementation, the method further includes:

at the resetting stage and the second noise reduction stage of each display period, pulling up the potential of the pull-down node to a high potential by the pull-down node control module, so as to control the pull-up node to be at a low potential by the pull-up node control module and control the gate driving signal output end to output a low level by the output noise reduction transistor.

In yet another aspect, the present disclosure provides in one embodiment a gate driver circuit including a plurality of levels of the above-mentioned shift register units arranged on an array substrate. An input end of a first-level shift register unit is configured to receive an ON signal. Apart from the first-level shift register unit, an input end of a current-level shift register unit is connected to a gate driving signal output end of a previous-level shift register unit. Apart from a last-level shift register unit, a resetting end of the current-level shift register unit is connected to a gate driving signal output end of a next-level shift register unit. A resetting end of the last-level shift register unit is configured to receive a resetting signal.

In still yet another aspect, the present disclosure provides in one embodiment a display device including the above-mentioned gate driver circuit.

According to the shift register unit, its driving method, the gate driver circuit and the display device in the embodiments of the present disclosure, the noise reduction is continuously performed using each element when the gate driving signal output end is inactive, so as to minimize the noise interference. As a result, it is able to prevent the occurrence of a coupling voltage generated due to the clock signal and improve the yield. In addition, it is able to reduce the number of the TFTs, thereby to provide a narrow bezel and reduce the production cost while achieving bi-direction scanning.

### BRIEF DESCRIPTION OF THE DRAWINGS

FIG. 1 is a schematic view showing a shift register unit according to one embodiment of the present disclosure;

FIG. 2 is a schematic view showing the shift register unit according to another embodiment of the present disclosure;

FIG. 3 is a schematic view showing a gate driver circuit according to one embodiment of the present disclosure;

FIG. 4 is a circuit diagram of an n^{th}-level shift register unit G(n) for forward scanning according to the first embodiment of the present disclosure;

FIG. 5 is a sequence diagram of the shift register unit in FIG. 4 during the forward scanning;

FIG. 6 is a circuit diagram of the n^{th}-level shift register unit G(n) for forward scanning according to the second embodiment of the present disclosure;

FIG. 7 is a sequence diagram of the shift register unit in FIG. 6 during the forward scanning;

FIG. 8 is a circuit diagram of the n^{th}-level shift register unit G(n) for backward scanning according to the first embodiment of the present disclosure; and

FIG. 9 is a sequence diagram of the shift register unit in FIG. 8 during the backward scanning.

### DETAILED DESCRIPTION

The present disclosure will be described hereinafter in a clear and complete manner in conjunction with the drawings and the embodiments. Obviously, the following embodiments are merely a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

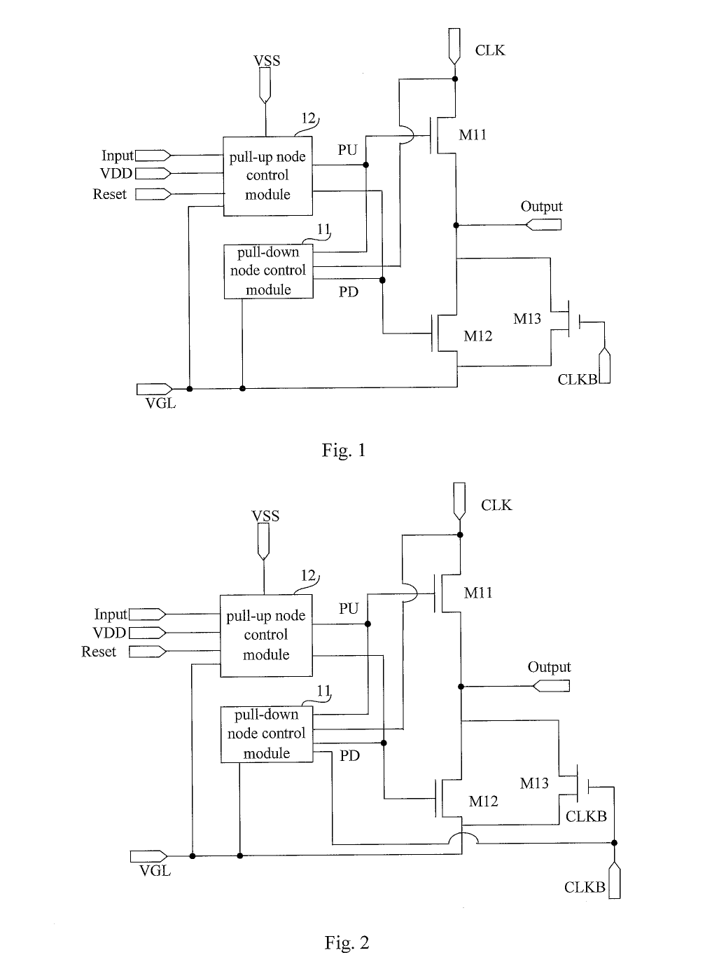

As shown in FIG. 1, the present disclosure provides in one embodiment a shift register unit, which includes an input end Input, a gate driving signal output end Output and a resetting end Reset. The shift register unit further includes:

a pull-up transistor M11, a gate electrode of which is connected to a pull-up node PU, a first electrode of which is configured to receive a first clock signal CLK, and a second electrode of which is connected to the gate driving signal output end Output;

a pull-down transistor M12, a gate electrode of which is connected to a pull-down node PD, a first electrode of which is connected to the gate driving signal output end Output, and a second electrode of which is configured to receive a first low level VGL;

a pull-down node control module 11 configured to receive the first low level VGL and the first clock signal CLK, connected to the pull-up node PU and the pull-down node PD, and configured to control the pull-down node PD to be at a low potential at a pre-charging stage of each display period, maintain the pull-down node PD at the low potential at an outputting stage of each display period, pull up a potential of the pull-down node PD to a high potential at a first noise reduction stage of each display period so as to turn on the pull-down transistor M12, and thereby to enable the gate driving signal output end Output to output a low level;

a pull-up node control module 12 configured to receive a high level VDD, the first low level VGL and a second low level VSS, connected to the pull-up node PU, the pull-down node PD, the input end Input and the resetting end Reset, and configured to, pull up a potential of the pull-up node PU to a high potential at the pre-charging stage of each display period, control the potential of the pull-up node PU to be bootstrapped at the outputting stage of each display period so as to maintain the pull-up transistor M11 in an on state and enable the gate driving signal output end Output to output the first clock signal CLK, pull down the potential of the pull-up node PU to a low potential at a resetting stage of each display period, and maintain the pull-up node PU to be at a low potential at the first noise reduction stage and a second noise reduction stage of each display period so as to turn off the pull-up transistor M11; and

an output noise reduction transistor M13, a gate electrode of which is configured to receive a second clock signal CLKB, a first electrode of which is connected to the gate driving signal output end Output, a second electrode of which is configured to receive the first low level VGL, and which is configured to be turned on at the pre-charging stage, the resetting stage and the second noise reduction stage of each display period so as to perform noise reduction on the gate driving signal output end Output, thereby to enable the gate driving signal output end Output to output a low level.

In this embodiment, the pull-up transistor M11 and the pull-down transistor M12 are both n-type transistors, and the first clock signal CLK is of a phase reverse to the second clock signal CLKB.

According to the shift register unit in the embodiment of the present disclosure, it is able to continuously perform noise reduction when the gate driving signal output is inactive and minimize noise interference, thereby to prevent the occurrence of a coupling voltage generated due to the clock signals and improve the yield.

The transistors adopted in all embodiments of the present disclosure may be TFTs, field-effect transistors (FETs), or any other elements having the same characteristics. In order to differentiate the other two electrodes apart from the gate electrode, the first electrode may be a source or drain electrode, while the second electrode may be a drain or source electrode. In addition, depending on their characteristics, the transistors may be n-type or p-type transistors, and in the driver circuit according to the embodiments of the present disclosure, all the transistors are n-type transistors. It should be appreciated that, p-type transistors may also be adopted, which also fall within the scope of the present disclosure.

During the implementation, as shown in FIG. 2, the pull-down node control module 11 is further configured to receive the second clock signal CLKB, and pull up the potential of the pull-down node PD to a high potential at the resetting stage and the second noise reduction stage of each display period, so as to control the pull-up node PU to be at a low potential by the pull-up node control module 12 and enable the gate driving signal output end Output to output a low level by the output noise reduction transistor M13.

As shown in FIG. 2, through the output noise reduction transistor M13, the pull-down node control module 11 and the pull-up node control module 12 may control the gate driving signal output end Output to output a low level at the resetting stage and the second noise reduction stage of each display period, so as to further reduce the noise.

During the implementation, the pull-down node control module includes:

a first pull-down node control transistor, a gate electrode of which is connected to the pull-up node, a first electrode of which is connected to the pull-down node, and a second electrode of which is configured to receive the first low level; and

a pull-down node control capacitor connected between the first pull-down node and a first clock signal output end.

During the implementation, the pull-down node control module further includes:

a second pull-down node control transistor, a gate electrode of which is configured to receive the second clock signal, a first electrode of which is connected to the pull-down node, and a second electrode of which is configured to receive the second clock signal.

During the implementation, the pull-up node control module includes a first transistor, a second transistor, a pull-up node control transistor and a storage capacitor. A gate electrode of the pull-up node control transistor is connected to the pull-down node, a first electrode thereof is configured to receive the first low level, and a second electrode thereof is connected to the pull-up node. The storage capacitor is connected between the pull-up node and the gate driving signal output end. During forward scanning, a gate electrode of the first transistor is connected to the input end, a first electrode of the first transistor is configured to receive the high level, a second electrode of the first transistor is connected to the pull-up node, a gate electrode of the second transistor is connected to the resetting end, a first electrode of the second transistor is connected to the pull-up node, and a second electrode of the second transistor is configured to receive the second low level. During backward scanning, the gate electrode of the first transistor is connected to the resetting end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

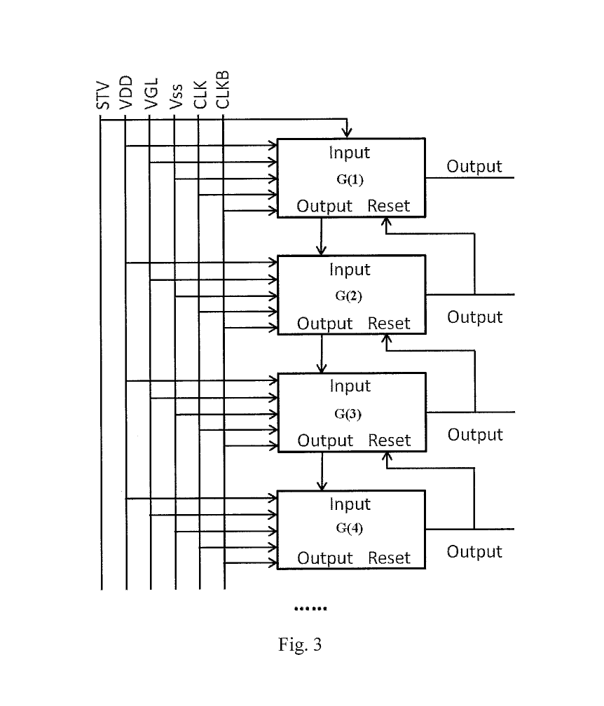

As shown in FIG. 3, the present disclosure provides in one embodiment a gate driver circuit including a plurality of levels of shift register units arranged on an array substrate. An input end of a first-level shift register unit G(1) is configured to receive an ON signal STY. Apart from the first-level shift register unit, an input end INPUT of a current-level shift register unit is connected to a gate driving signal output end OUTPUT of a previous-level shift register unit. Apart from a last-level shift register unit, a resetting end of the current-level shift register unit is connected to a gate driving signal output end OUTPUT of a next-level shift register unit. A resetting end of the last-level shift register unit is configured to receive a resetting signal (not shown).

As shown in FIG. 3, G(2) represents a second-level shift register unit, G(3) represents a third-level shift register unit, and G(4) represents a fourth-level shift register unit.

The shift register unit in the embodiments of the present disclosure will be described hereinafter.

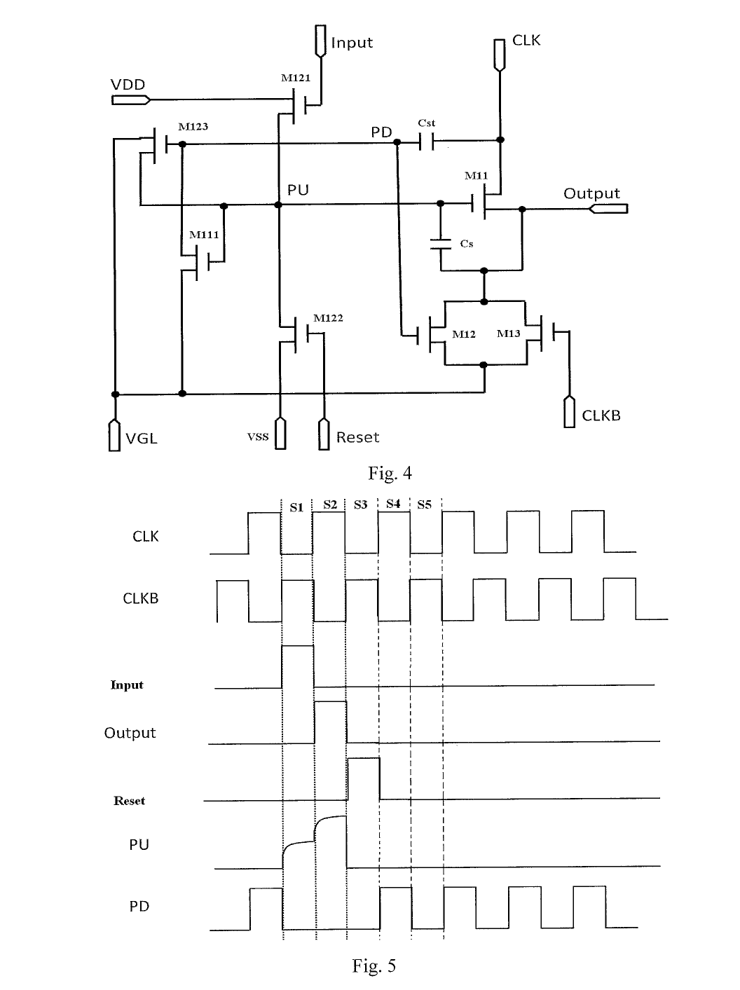

As shown in FIG. 4, in the first embodiments, an n^{th}-level shift register unit G(n) for forward scanning (n is a positive integer) includes the input end Input, the gate driving signal output end Output, the resetting end Reset, the pull-up transistor M11, the pull-down transistor M12, the pull-down node control module 11, the pull-up node control module 12 and the output noise reduction transistor M13. The gate electrode of the pull-up transistor M11 is connected to the pull-up node PU, the first electrode thereof is configured to receive the first clock signal CLK, and the second electrode thereof is connected to the gate driving signal output end Output. The gate electrode of the pull-down transistor M12 is connected to the pull-down node PD, the first electrode thereof is connected to the gate driving signal output end Output, and the second electrode thereof is configured to receive the first low level VGL

The pull-down node control module 11 includes:

a first pull-down node control transistor M111, a gate electrode of which is connected to the pull-up node PU, a first electrode of which is connected to the pull-down node PD, and a second electrode of which is configured to receive the first low level VGL; and

a pull-down node control capacitor Cst connected between the first pull-down node PD and a first clock signal output end outputting the first clock signal CLK.

The pull-up node control module 12 includes a first transistor M121, a second transistor M122, a pull-up node control transistor M123 and a storage capacitor Cs. A gate electrode of the pull-up node control transistor M123 is connected to the pull-down node PD, a first electrode thereof is configured to receive the first low level VGL, and a second electrode thereof is connected to the pull-up node PU. The storage capacitor Cs is connected between the pull-up node PU and the gate driving signal output end Output. A gate electrode of the first transistor M121 is connected to the input end Input, a first electrode thereof is configured to receive the high level VDD, and a second electrode thereof is connected to the pull-up node PU. A gate electrode of the second transistor M122 is connected to the resetting end Reset, a first electrode thereof is connected to the pull-up node PU, and a second electrode thereof is configured to receive the second low level VSS. A gate electrode of the output noise reduction transistor M13 is configured to receive the second clock signal CLKB, a first electrode thereof is connected to the gate driving signal output end Output, and a second electrode thereof is configured to receive the first low level VGL. At the pre-charging stage, the resetting stage and the second noise reduction stage of each display period, the output noise reduction transistor M13 is turned on, so as to perform noise reduction on the gate driving signal output end Output, thereby to enable the gate driving signal output end Output to output a low level.

FIG. 5 shows a working procedure of the shift register unit in FIG. 4 within one display period during the forward scanning.

At the pre-charging stage S1, Input receives a high level (i.e., Input is connected to Output of the previous-level shift register unit) so as to turn on M121. CLK is at a low level, and Cs is charged by VDD via M121, so as to pull up the potential of PU. PU is at a high level, so as to turn on M111 and pull down the potential of PD to a low level, and at this time, M12 and M123 are both turned off. Meanwhile, CLKB is at a high level so as to perform noise reduction on Output, thereby to output a gate driving signal in a stable manner.

At the output stage S2, Input receives a low level, M121 is turned off, PU is maintained at a high level, and M11 is maintained in an on state. At this time, CLK is at a high level, and PU is continuously pulled up due to bootstrapping, so M11 is maintained in the on state and the gate driving signal is outputted. PU is at a high level, M111 is still in the on state, so M12 and M123 is maintained in an off state. Meanwhile, CLKB is at a low level, and M3 is turned off, so as to output the gate driving signal in a stable manner.

At the resetting stage S3, Reset receives a high level (i.e., the gate driving signal from the next-level shift register unit) so that M122 is in the on state. The potential of PU is pulled down, so as to turn off M11 and M111. Meanwhile, CLKB is at a high level too, and M13 is in the on state, so as to pull down the gate driving signal to VGL.

At the first noise reduction stage S4, CLK is at a high level, M123 is turned on, and the potential of PU is pulled down to VGL. M111 is turned off, so as to pull up the potential of PD to a high level. M12 is turned on, so as to perform noise reduction on Output. Meanwhile, PD is at a high level, and M123 is turned on, so as to perform noise reduction on PU. As a result, it is able to eliminate a coupling noise voltage generated by CLK, thereby to achieve the output at a low level and output the gate driving signal in a stable manner.

At the second noise reduction stage S5, CLK is at a low level, M111 is turned off, PD is at a low level, and M123 and M12 are both turned off. Meanwhile, CLKB is at a high level, and M13 is turned on, so as to perform noise reduction on Output.

Before a next frame arrives, the first noise reduction stage S4 and the second noise reduction stage S5 are repeated all the time by the shift register unit, so as to perform noise reduction on the pull-up node PU and the gate driving signal output end Output continuously.

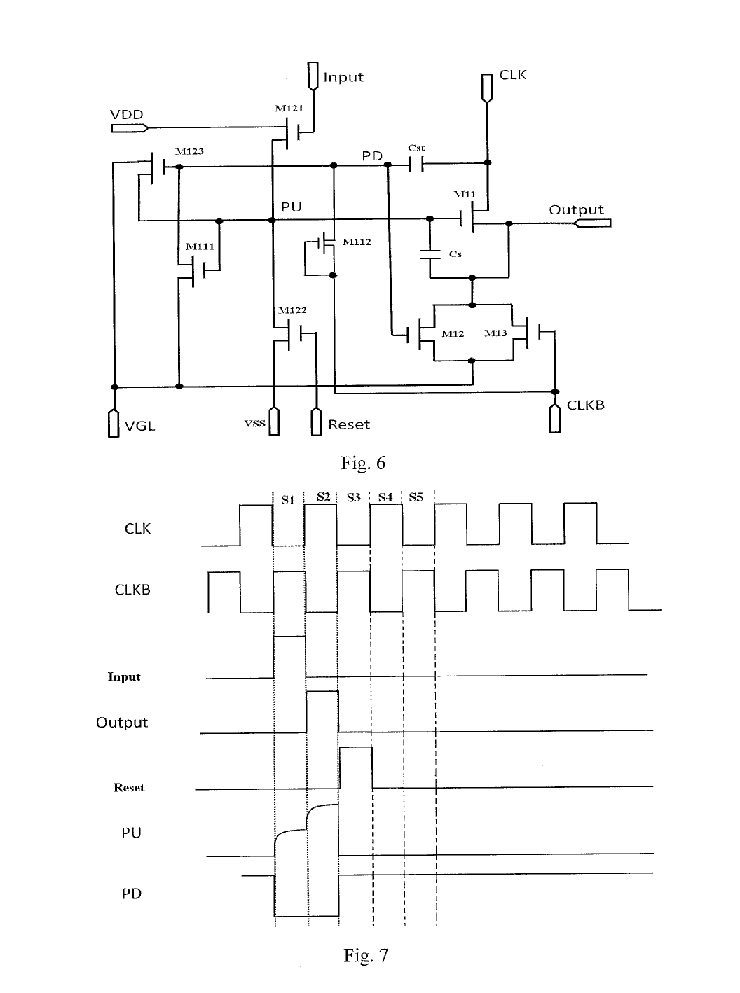

FIG. 6 shows the n^{th}-level shift register unit G(n) for forward scanning in the second embodiment (n is a positive integer). As compared with the first embodiment as shown in FIG. 4, the shift register unit further includes a second pull-down node control transistor M112, a gate electrode of which is configured to receive the second clock signal CLKB, a first electrode of which is connected to the pull-down node PD, and a second electrode of which is configured to receive the second clock signal CLKB.

FIG. 7 shows a working procedure of the shift register unit in FIG. 6 within one display period during the forward scanning.

At the pre-charging stage S1, Input receives a high level (i.e., Input is connected to Output of the previous-level shift register unit) so as to turn on M121. CLK is at a low level, and Cs is charged by VDD via M121, so as to pull up the potential of PU. PU is at a high level, so as to turn on M111. At this time, CLKB is at a high level, and a proportion of M111 to M112 may be adjusted, so that the potential of PD may still be pulled down to a low level when M112 is in the on state. PD is at a low level, so M12 and M123 are both turned off. Meanwhile, CLKB is at a high level, so as to perform noise reduction on Output, thereby to output the gate driving signal in a stable manner.

At the output stage S2, Input receives a low level, M121 is turned off, the potential of PU is maintained at a high level, and M11 is maintained in an on state. At this time, CLK is at a high level, the potential of PU is pulled up continuously due to bootstrapping, so M11 is maintained in the on state and the gate driving signal is outputted. PU is at a high potential, and M111 is still in the on state. Meanwhile, CLKB is at a low level, M112 is in an off state, so M12 and M123 are both maintained in the off state. CLKB is at a low level, so M13 is in the off state, and as a result, it is able to output the gate driving signal in a stable manner.

At the resetting stage S3, Reset receives a high level (i.e., the gate driving signal from the next-level shift register unit), so as to turn on M122 and pull down the potential of PU, thereby to turn off M11 and M111. Meanwhile, CLKB is also at a high level, M13 is in the on state, and the gate driving signal is pulled down to VGL. CLKB is at a high level, so M112 is in the on state, PD is at a high potential, and M123 and M12 are both in the on state. Meanwhile, PU and Output are discharged.

At the first noise reduction stage S4, CLK is at a high level, and CLKB is at a low level. At this time, PU is at a low potential, M111 and M112 are both in the off state, the potential of PD is pulled up to a high potential by Cst, and M12 is turned on, so as to perform noise reduction on Output. Meanwhile, PD is at a high potential, and M123 is turned on, so as to perform noise reduction on PU. As a result, it is able to eliminate a coupling noise voltage generated by CLK, thereby to achieve the output at a low level and output the gate driving signal in a stable manner.

At the second noise reduction stage S5, CLK is at a low level, CLKB is at a high level, M111 is turned off, M112 is turned on, PD is still at a high potential, and M123, M12 and M13 are all turned on, so as to perform noise reduction on Output and PU.

Before a next frame arrives, the first noise reduction stage S4 and the second noise reduction stage S5 are repeated all the time by the shift register unit, so as to perform noise reduction on the pull-up node PU and the gate driving signal output end Output continuously.

According to the n^{th}-level shift register unit G(n) in the second embodiment as shown in FIG. 6, due to M112, it is able to further control, through the output noise reduction transistor M13, the gate driving signal output end Output to output a low level at the resetting stage and the second noise reduction stage of each display period, thereby to further reduce the noise.

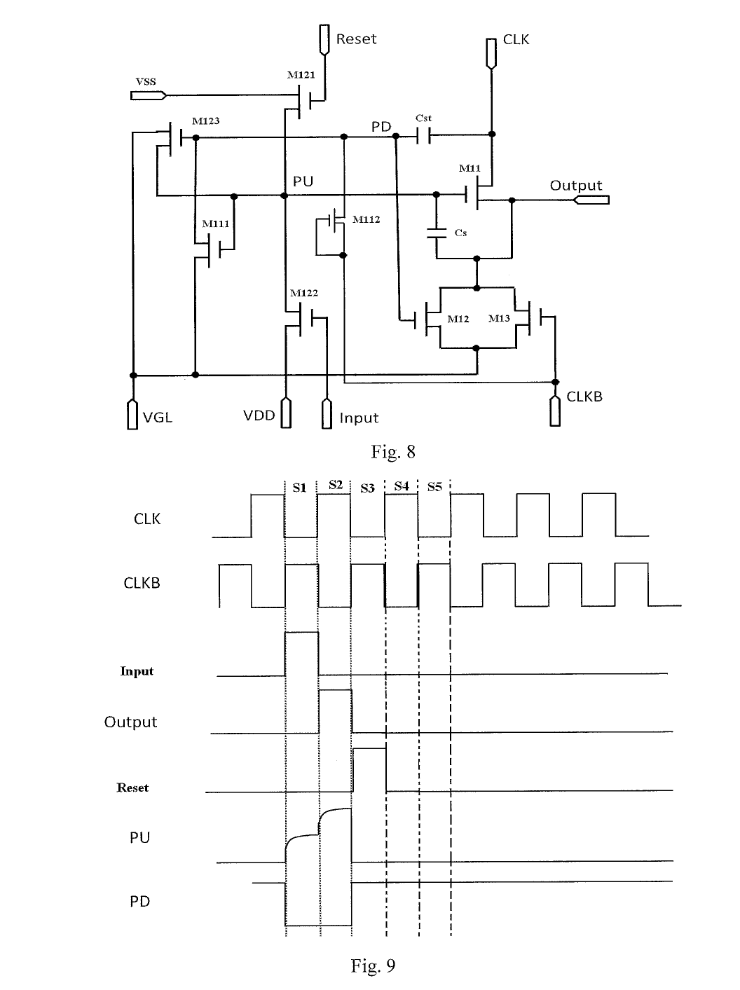

FIG. 8 shows the n^{th}-level shift register unit G(n) (n is a positive integer) for backward scanning (where positions of Reset and Input, as well as positions of VSS and VDD, are exchanged with each other, respectively, as compared with the forward scanning) in the first embodiment. The shift register unit includes the input end Input, the gate driving signal output end Output, the resetting end Reset, the pull-up transistor M11, the pull-down transistor M12, the pull-down node control module 11, the pull-up node control module 12 and the output noise reduction transistor M13. The gate electrode of the pull-up transistor M11 is connected to the pull-up node PU, the first electrode thereof is configured to receive the first clock signal CLK, and the second electrode thereof is connected to the gate driving signal output end Output. The gate electrode of the pull-down transistor M12 is connected to the pull-down node PD, the first electrode thereof is connected to the gate driving signal output end Output, and the second electrode thereof is configured to receive the first low level VGL.

The pull-down node control module 11 includes:

a first pull-down node control transistor M111, a gate electrode of which is connected to the pull-up node PU, a first electrode of which is connected to the pull-down node PD, and a second electrode of which is configured to receive the first low level VGL;

a second pull-down node control transistor M112, a gate electrode of which is configured to receive the second clock signal CLKB, a first electrode of which is connected to the pull-down node PD, and a second electrode of which is configured to receive the second clock signal CLKB; and a pull-down node control capacitor Cst connected between the pull-down node PD and a first clock signal output end outputting the first clock signal CLK.

The pull-up node control module 12 includes a first transistor M121, a second transistor M122, a pull-up node control transistor M123 and a storage capacitor Cs. A gate electrode of the pull-up node control transistor M123 is connected to the pull-down node PD, a first electrode thereof is configured to receive the first low level VGL, and a second electrode thereof is connected to the pull-up node PU. The storage capacitor Cs is connected between the pull-up node PU and the gate driving signal output end Output. A gate electrode of the first transistor M121 is connected to the resetting end Reset, a first electrode thereof is configured to receive the second low level VSS, and a second electrode thereof is connected to the pull-up node PU. A gate electrode of the second transistor M122 is connected to the input end Input, a first electrode thereof is connected to the pull-up node PU, and a second electrode thereof is configured to receive the high level VDD. A gate electrode of the output noise reduction transistor M13 is configured to receive the second clock signal CLKB, a first electrode thereof is connected to the gate driving signal output end Output, and a second electrode thereof is configured to receive the first low level VGL. At the pre-charging stage, the resetting stage and the second noise reduction stage of each display period, the output noise reduction transistor M13 is turned on, so as to perform noise reduction on the gate driving signal output end Output, thereby to enable the gate driving signal output end Output to output a low level.

FIG. 9 shows a working procedure of the shift register unit in FIG. 8 within one display period during the backward scanning.

At the pre-charging stage S1, Input receives a high level (i.e., Input is connected to Output of a previous-level shift register unit), so as to turn on M122. CLK is at a low level, and Cs is charged by VDD via M122, so as to pull up the potential of PU. PU is at a high level so as to turn on M111. At this time, CLKB is at a high level, and a proportion of M111 to M112 may be adjusted, so that the potential of PD may still be pulled down to a low level when M112 is in the on state. PD is at a low level so as to turn off M12 and M123. Meanwhile, CLKB is at a high level, so as to perform noise reduction on Output, thereby to output the gate driving signal in a stable manner.

At the output stage S2, Input receives a low level, M122 is turned off, PU is maintained at a high level and M11 is maintained in the on state. CLK is at a high level, the potential of PU is continuously pulled up due to bootstrapping, so that M11 is maintained in the on state and the gate driving signal is outputted. PU is at a high potential, and M111 is still in the on state. Meanwhile, CLKB is at a low level, M112 is in the off state, so M12 and M123 are maintained in the off state. Because CLKB is at a low level, M13 is in the off state, so it is able to output the gate driving signal in a stable manner.

At the resetting stage S3, Reset receives a high level (i.e., the gate driving signal from a next-level shift register unit) so as to turn on M121. The potential of PU is pulled down, so as to turn off M11 and M111. Meanwhile, CLKB is also at a high level, M13 is in the on state, so as to pull down the gate driving signal to VGL. Because CLKB is at a high level, M112 is in the on state, PD is at a high potential, and M123 and M12 are both in the on state. Meanwhile, PU and Output are both discharged.

At the first noise reduction stage S4, CLK is at a high level, and CLKB is at a low level. At this time, PU is at a low potential, M111 and M112 are both in the off state, the potential of PD is pulled up by Cst to a high potential, and M12 is turned on, so as to perform noise reduction on PU. As a result, it is able to eliminate a coupling noise voltage generated due to CLK, thereby to achieve the output at a low level and output the gate driving signal in a stable manner.

At the second noise reduction stage S5, CLK is at a low level, CLKB is at a high level, M111 is turned off, M112 is turned on, PD is still at a high potential, and M123, M12 and M13 are turned on, so as to perform noise reduction on Output and PU.

Before a next frame arrives, the first noise reduction stage S4 and the second noise reduction stage S5 are repeated all the time by the shift register unit, so as to perform noise reduction on the pull-up node PU and the gate driving signal output end Output continuously.

As mentioned above, it is able for a shift register including a plurality of levels of the shift register units to achieve both the forward scanning and the backward scanning merely through one circuit structure, as long as a signal applied to the first electrode of the first transistor and a signal applied to the second electrode of the second transistor are changed correspondingly during the switching of the scanning directions. As a result, it is able to reduce the number of the desired TFTs, thereby to reduce the power consumption.

The present disclosure further provides in one embodiment a gate driver circuit including a plurality of levels of the shift register units, so as to achieve bi-direction scanning while achieving a gate driving function. Also, as mentioned above, it is able to reduce the number of signal lines and TFTs, thereby to provide a narrow bezel, improve the yield, reduce the production cost and improve the stability of the gate shift register. Furthermore, the noise reduction is continuously performed using each element when the gate driving signal output end is inactive, so as to minimize the noise interference. As a result, it is able to prevent the occurrence of a coupling voltage generated due to CLK and improve the yield. In addition, it is able to prevent an abnormal output from the shift register unit due to threshold voltage drift of the TFT itself, and prolong a service life of the shift register unit.

The present disclosure further provides in one embodiment a method for driving the above-mentioned shift register unit, including, within each display period and during forward scanning and backward scanning, steps of:

at the pre-charging stage, receiving a high level by the input end, receiving a low level by the resetting end, enabling the first clock signal to be at a low level, enabling the second clock signal to be at a high level, pulling up the potential of the pull-up node to a high potential by the pull-up node control module so as to turn on the pull-up transistor, controlling the pull-down node to be at a low potential by the pull-down node control module so as to turn off the pull-down transistor, turn on the output amplification transistor and enable the gate driving signal output end to output a low level;

at the outputting stage, receiving a low level by the input end, receiving a low level by the resetting end, enabling the first clock signal to be at a high level, enabling the second clock signal to be at a low level, bootstrapping the potential of the pull-up node by the pull-up node control module so as to maintain the pull-up transistor in an on state and enable the gate driving signal output end to output the first clock signal, and maintaining the potential of the pull-down node to be at a low potential by the pull-down node control module;

at the resetting stage, receiving a low level by the input end, receiving a high level by the resetting end, enabling the first clock signal to be at a low level, enabling the second clock signal to be at a high level, pulling down the potential of the pull-up node to a low potential by the pull-up node control module, so as to turn on the output noise reduction transistor, perform noise reduction on the gate driving signal output end, and enable the gate driving signal output end to output a low level;

at the first noise reduction stage, receiving a low level by the input end, receiving a low level by the resetting end, enabling the first clock signal to be at a high level, enabling the second clock signal to be at a low level, maintaining the potential of the pull-up node to be a low potential by the pull-up node control module so as to turn off the pull-up transistor, and pulling up the potential of the pull-down node to a high potential by the pull-down node control module so as to turn on the pull-down transistor and enable the gate driving signal output end to output a low level; and

at the second noise reduction stage, receiving a low level by the input end, receiving a low level by the resetting end, enabling the first clock signal to be at a low level, enabling the second clock signal to be at a high level, maintaining the potential of the pull-up node to be a low potential by the pull-up node control module so as to turn off the pull-up transistor, turn on the output noise reduction transistor, thereby to perform noise reduction on the gate driving signal output end and enable the gate driving signal output end to output a low level.

During the implementation, the method further includes performing the steps at the first noise reduction stage and the second noise reduction stage repeatedly after the second noise reduction stage of one display period and before a next display period.

During the implementation, the method further includes:

at the resetting stage and the second noise reduction stage of each display period, pulling up the potential of the pull-down node to a high potential by the pull-down node control module, so as to control the pull-up node to be at a low potential by the pull-up node control module and control the gate driving signal output end to output a low level by the output noise reduction transistor.

The present disclosure further provides in one embodiment a display device including the above-mentioned gate driver circuit. The display device may be a liquid crystal display, a liquid crystal TV, an organic light-emitting diode (OLED) display panel, an OLED display, an OLED TV, or an electronic paper.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

What is claimed is:

1. A shift register unit, comprising an input end, a gate driving signal output end and a resetting end, further comprising:
a pull-up transistor, a gate electrode of which is connected to a pull-up node, a first electrode of which is configured to receive a first clock signal, and a second electrode of which is connected to the gate driving signal output end;
a pull-down transistor, a gate electrode of which is connected to a pull-down node, a first electrode of which is connected to the gate driving signal output end, and a second electrode of which is configured to receive a first low level;
a pull-down node control module configured to receive the first low level and the first clock signal, connected to the pull-up node and the pull-down node, and configured to control the pull-down node to be at a low potential at a pre-charging stage of each display period, maintain the pull-down node at the low potential at an outputting stage of each display period, pull up a potential of the pull-down node to a high potential at a first noise reduction stage of each display period so as to turn on the pull-down transistor, and thereby to enable the gate driving signal output end to output a low level;
a pull-up node control module configured to receive a high level, the first low level and a second low level, connected to the pull-up node, the pull-down node, the input end and the resetting end, and configured to, pull up a potential of the pull-up node to a high potential at the pre-charging stage of each display period, control the potential of the pull-up node to be bootstrapped at the outputting stage of each display period so as to maintain the pull-up transistor in an on state and enable the gate driving signal output end to output the first clock signal, pull down the potential of the pull-up node to a low potential at a resetting stage of each display period, and maintain the pull-up node to be at a low potential at the first noise reduction stage and a second noise reduction stage of each display period so as to turn off the pull-up transistor; and
an output noise reduction transistor, a gate electrode of which is configured to receive a second clock signal, a first electrode of which is connected to the gate driving signal output end, a second electrode of which is configured to receive the first low level, and which is configured to be turned on at the pre-charging stage, the resetting stage and the second noise reduction stage of each display period so as to perform noise reduction on the gate driving signal output end, thereby to enable the gate driving signal output end to output a low level,
wherein the first clock signal is of a phase reverse to the second clock signal.

2. The shift register unit according to claim 1, wherein the pull-down node control module is further configured to receive the second clock signal, and pull up the potential of the pull-down node to a high potential at the resetting stage and the second noise reduction stage of each display period, so as to control the pull-up node to be at a low potential by the pull-up node control module and enable the gate driving signal output end to output a low level by the output noise reduction transistor.

3. The shift register unit according to claim 2, wherein the pull-down node control module comprises:
a first pull-down node control transistor, a gate electrode of which is connected to the pull-up node, a first electrode of which is connected to the pull-down node, and a second electrode of which is configured to receive the first low level; and
a pull-down node control capacitor connected between the pull-down node and a first clock signal output end.

4. The shift register unit according to claim 3, wherein the pull-down node control module further comprises:
a second pull-down node control transistor, a gate electrode of which is configured to receive the second clock signal, a first electrode of which is connected to the pull-down node, and a second electrode of which is configured to receive the second clock signal.

5. The shift register unit according to claim 1, wherein the pull-up node control module comprises a first transistor, a second transistor, a pull-up node control transistor and a storage capacitor,
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of the second transistor is connected to the resetting end, a first electrode of the second transistor is connected to the pull-up node, and a second electrode of the second transistor is configured to receive the second low level; and
during backward scanning, the gate electrode of the first transistor is connected to the resetting end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

6. The shift register unit according to claim 2, wherein the pull-up node control module comprises a first transistor, a second transistor, a pull-up node control transistor and a storage capacitor,
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of the second transistor is connected to the resetting end, a first electrode of the second transistor is connected to the pull-up node, and a second electrode of the second transistor is configured to receive the second low level; and
during backward scanning, the gate electrode of the first transistor is connected to the resetting end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

7. The shift register unit according to claim 3, wherein the pull-up node control module comprises a first transistor, a second transistor, a pull-up node control transistor and a storage capacitor,
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of the second transistor is connected to the resetting end, a first electrode of the second transistor is connected to the pull-up node, and a second electrode of the second transistor is configured to receive the second low level; and
during backward scanning, the gate electrode of the first transistor is connected to the resetting end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

8. The shift register unit according to claim 4, wherein the pull-up node control module comprises a first transistor, a second transistor, a pull-up node control transistor and a storage capacitor,
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of the second transistor is connected to the resetting end, a first electrode of the second transistor is connected to the pull-up node, and a second electrode of the second transistor is configured to receive the second low level; and
during backward scanning, the gate electrode of the first transistor is connected to the resetting end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

9. A method for driving the shift register unit according to claim 1, comprising, within each display period and during forward scanning and backward scanning, steps of:
at a pre-charging stage, receiving a high level by an input end, receiving a low level by a resetting end, enabling a first clock signal to be at a low level, enabling a second clock signal to be at a high level, pulling up a potential of a pull-up node to a high potential by a pull-up node control module so as to turn on a pull-up transistor, controlling a pull-down node to be at a low potential by a pull-down node control module so as to turn off a pull-down transistor, turn on an output noise reduction transistor and enable a gate driving signal output end to output a low level;
at an outputting stage, receiving a low level by the input end, receiving a low level by the resetting end, enabling the first clock signal to be at a high level, enabling the second clock signal to be at a low level, bootstrapping the potential of the pull-up node by the pull-up node control module so as to maintain the pull-up transistor in an on state and enable the gate driving signal output end to output the first clock signal, and maintaining the potential of the pull-down node to be at a low potential by the pull-down node control module;
at a resetting stage, receiving a low level by the input end, receiving a high level by the resetting end, enabling the first clock signal to be at a low level, enabling the second clock signal to be at a high level, pulling down the potential of the pull-up node to a low potential by the pull-up node control module, so as to turn on the output noise reduction transistor, perform noise reduction on the gate driving signal output end, and enable the gate driving signal output end to output a low level;
at a first noise reduction stage, receiving a low level by the input end, receiving a low level by the resetting end, enabling the first clock signal to be at a high level, enabling the second clock signal to be at a low level, maintaining the potential of the pull-up node to be a low potential by the pull-up node control module so as to turn off the pull-up transistor, and pulling up the potential of the pull-down node to a high potential by the pull-down node control module so as to turn on the pull-down transistor and enable the gate driving signal output end to output a low level; and
at a second noise reduction stage, receiving a low level by the input end, receiving a low level by the resetting end, enabling the first clock signal to be at a low level, enabling the second clock signal to be at a high level, maintaining the potential of the pull-up node to be a low potential by the pull-up node control module so as to turn off the pull-up transistor, turn on the output noise reduction transistor, thereby to perform noise reduction on the gate driving signal output end and enable the gate driving signal output end to output a low level.

10. The method according to claim 9, further comprising:
performing the steps at the first noise reduction stage and the second noise reduction stage repeatedly after the second noise reduction stage of one display period and before a next display period.

11. The method according to claim 9, further comprising:
at the resetting stage and the second noise reduction stage of each display period, pulling up the potential of the pull-down node to a high potential by the pull-down node control module, so as to control the pull-up node to be at a low potential by the pull-up node control module and control the gate driving signal output end to output a low level by the output noise reduction transistor.

12. The method according to claim 10, further comprising:
at the resetting stage and the second noise reduction stage of each display period, pulling up the potential of the pull-down node to a high potential by the pull-down node control module, so as to control the pull-up node to be at a low potential by the pull-up node control module and control the gate driving signal output end to output a low level by the output noise reduction transistor.

13. A gate driver circuit, comprising a plurality of levels of the shift register units according to claim 1 arranged on an array substrate,
wherein an input end of a first-level shift register unit is configured to receive an ON signal;
apart from the first-level shift register unit, an input end of a current-level shift register unit is connected to a gate driving signal output end of a previous-level shift register unit;
apart from a last-level shift register unit, a resetting end of the current-level shift register unit is connected to a gate driving signal output end of a next-level shift register unit; and
a resetting end of the last-level shift register unit is configured to receive a resetting signal.

14. A display device comprising the gate driver circuit according to claim 13.
